(19) United States
(12) Patent Application Publication
(10) Pub. No.: US 2022/0093366 A1
(43) Pub. Date: Mar. 24, 2022

(54) SHOWERHEAD FOR DEPOSITION TOOLS HAVING MULTIPLE PLENUMS AND GAS DISTRIBUTION CHAMBERS

(71) Applicant: LAM RESEARCH CORPORATION, Fremont, CA (US)

(72) Inventors: Michael J. JANICKI, Portland, OR (US); Curtis W. BAILEY, West Linn, OR (US)

(21) Appl. No.: 17/424,772

(22) PCT Filed: Jan. 23, 2020
(86) PCT No.: PCT/US2020/014813

§ 371 Date: Jul. 21, 2021

Related U.S. Application Data
(60) Provisional application No. 62/800,055, filed on Feb. 1, 2019.

(51) Int. Cl. H01J 37/32; C23C 16/455; C23C 16/50

(52) U.S. Cl. CPC H01J 37/32449; H01J 2237/3321; C23C 16/50; C23C 16/45565

(57) ABSTRACT

A deposition tool including a processing chamber, a substrate holder for holding a substrate to be processed within the processing chamber and a showerhead having a faceplate for distributing a first and/or second gas(es) and/or vapor(s) into the processing chamber. The showerhead includes first and second plenums, first and second chambers, each provided behind a backside of the faceplate, and first and second sets of holes, both formed through the faceplate of the showerhead, and in fluid communication with the first and second chambers respectively.

### CROSS REFERENCE TO RELATED APPLICATION

This application claims the benefit of priority of U.S. Application No. 62/800,055, filed Feb. 1, 2019, which is incorporated herein by reference for all purposes.

### BACKGROUND

The present invention relates to a deposition tool for depositing thin films onto substrates, and more particularly, to a showerhead for deposition tools having multiple chambers, each capable of distributing gas(es) and/or vapor(s) into a processing chamber without the need for a complex distribution network of cross-drill holes internal to the showerhead.

Various types of tools are commonly used for depositing various thin films onto substrate surfaces, such as semiconductor wafers, flat panel displays and/or photovoltaic devices. With such tools, a substrate to be processed is placed into a processing chamber. A showerhead, located in the processing chamber, supplies a combination of (a) reactant chemistry gas(es) and/or vapor(s) and (b) one or more process chemistry gas(es) and/or vapor(s) that contain the material to be deposited onto the substrate. Hereafter, reactant(s) and/or process chemistries may be referred to generically as “gas(es)” and/or “vapor(s)”.

Showerheads with one or more plenums for supplying the reactant and/or process chemistry or chemistries into a processing chamber are known. Internal to these showerheads, at least one network of cross-drill holes, in fluid communication with a plenum, is provided. The network includes cross-drilled holes that each extend (a) perpendicular to the direction of the plenum and (b) 90 degrees apart with respect to one another. A plurality of holes, perpendicular to the grid of cross-drill holes (i.e. axial with the plenum), are provided through faceplate of the showerhead. With this arrangement, gas(es) and/or vapor(s) are:

(1) Supplied to the showerhead via the plenum extending along the Z axis;

(2) Laterally distributed internal to the showerhead by the individual cross-drill holes of the network along the X and Y axes;

(3) Through the plurality of holes form in the faceplate along the Z axis and into the processing chamber.

There are a number of issues with showerheads that rely on one or more networks of cross-drill holes to internally and laterally distribute process and/or reactant gas(es) and/or vapor(s) within the showerhead prior to release into the processing chamber. First, it is very expensive and complicated to drill the complex network of cross-drill holes when machining the showerhead. Second, metal shavings, particles and residual drilling oil, resulting during machining, may remain in the cross-drill holes even after cleaning. These contaminants can potentially be released into the processing chamber during deposition, causing defects on the processed substrates. Third, it is difficult to uniformly circulate the gas(es) and/or vapor(s) throughout the complex cross-drill hole pattern. As a result, the process and/or reactant gas(es) and/or vapor(s) may not be uniformly distributed when dispensed above the substrate surface. Fourth, condensation of the gas(es) distributed through the network of cross-drill holes is more likely to occur. As a gas “turns a corner” when passing from one cross-drill hole to another cross-drill hole at 90 degrees, the temperature of the gas tends to drop. This temperature drop has been known to cause condensation, meaning the gas turns at least partially into a liquid. As a result, liquids may deposit onto substrate surface and the concentration of the gas(es) within the plasma is reduced to less than desired.

A showerhead that improves the distribution of gas(es) and/or vapor(s) within the processing chamber of a deposition tool is therefore needed.

### SUMMARY

A deposition tool including a processing chamber, a substrate holder for holding a substrate to be processed within the processing chamber and a showerhead having a faceplate for distributing a first and/or second gas(es) and/or vapor(s) into the processing chamber is disclosed.

In a non-exclusive embodiment, the showerhead includes a first plenum, a first chamber provided immediately behind a backside of the faceplate of the showerhead and a first set of holes formed through the faceplate and in fluid communication with the chamber. With this arrangement, first gas(es) and/or vapor(s) is/are supplied by and flow into the processing chamber via (a) the first plenum, (b) laterally within the first plenum chamber relative to the faceplate of the showerhead and (c) from the first plenum chamber into the processing chamber via the first set of holes.

In another embodiment, the showerhead further includes a second plenum and a second chamber. The second chamber is in fluid communication with the processing chamber through a second set of holes, which are (1) are formed through the faceplate of the showerhead and (2) extend via protrusions that span through the first chamber to the second chamber. With this arrangement, second gas(es) and/or vapor(s) is/are supplied by and flow into the processing chamber via (a) the second plenum, (b) laterally within the second chamber relative to the faceplate of the showerhead and (c) through the second set of holes.

In a specific, but non-exclusive embodiment, the protrusions are “ribs” that span through the first chamber to the second chamber. The ribs are also arranged in a concentric, radial pattern. With this configuration, the second set of holes is also arranged in a similar, concentric, radial pattern, on the faceplate of the showerhead. In other embodiments, the protrusions may assume any form suitable for fluidly connecting the first and second chambers and the second set of holes may be arranged in any pattern on the faceplate of the showerhead.

With the showerhead as described above, the first and/or second gas(es) and/or vapors are enabled to laterally flow relative to the backside of the faceplate of the showerhead within the first and second chambers without having to flow through a network of drilled cross-holes. As result, a number of benefits are realized, including (1) less complexity and cost in machining the showerhead during fabrication, (2) a reduction or elimination of metal shavings, particles and residual oil that otherwise results from drilling, (3) a more uniform distribution of gas(es) and/or vapors exiting the showerhead and (4) a reduction or elimination of condensation of the gas(es) and/or vapors resulting in particles and defects on the deposited substrate.

### BRIEF DESCRIPTION OF THE DRAWINGS

The present application, and the advantages thereof, may best be understood by reference to the following description taken in conjunction with the accompanying drawings in which:

FIG. 1 is a diagram of an exemplary deposition tool used for processing substrates in accordance with a non-exclusive embodiment of the invention.

FIGS. 2A-2B are perspective and exploded views of a showerhead used in the exemplary deposition tool in accordance with a non-exclusive embodiment of the invention.

FIGS. 3A-3B are perspective view of a faceplate and backside of the faceplate of the showerhead in accordance with a non-exclusive embodiment of the invention.

FIGS. 4A-4C are various cross section views of the showerhead in accordance with a non-exclusive embodiment of the invention.

In the drawings, like reference numerals are sometimes used to designate like structural elements. It should also be appreciated that the depictions in the figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are set forth in order to provide a thorough understanding of the present disclosure. It will be apparent, however, to one skilled in the art, that the present discloser may be practiced without some or all of these specific details. In other instances, well known process steps and/or structures have not been described in detail in order to not unnecessarily obscure the present disclosure.

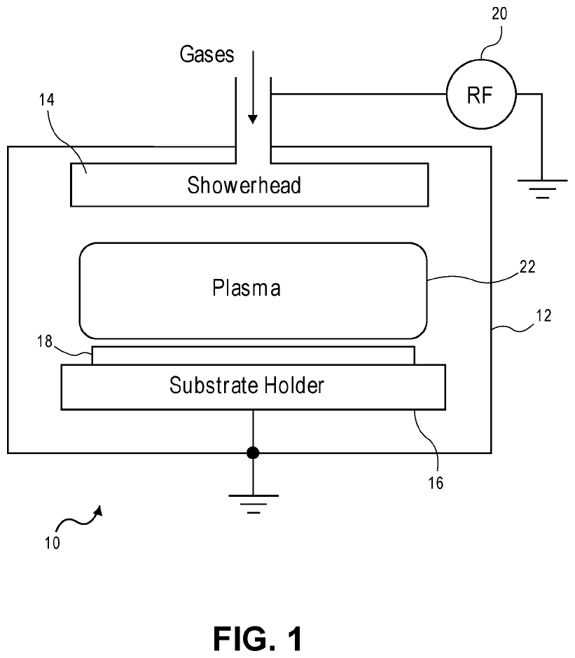

Referring to FIG. 1, a diagram of an exemplary Chemical Vapor Deposition (CVD) tool 10 is illustrated. The CVD tool 10 includes a processing chamber 12, a showerhead 14, a substrate holder 16 for holding and positioning a substrate 18 to be processed and a Radio Frequency (RF) generator 20. In various embodiments, the CVD tool 10 may be a Plasma Enhanced (PECVD), a Low Pressure (LPCVD), an Ultra High Vacuum (UHVCVD), an Atomic Layer Deposition (ALD), a Plasma-Enhanced Atomic Layer Deposition (PEALD) or any other type of CVD tool.

The CVD tool 10, regardless of the type, may be used to deposit a wide range of materials or films onto the substrate 18. Such materials or films may include, but are not limited to, polysilicon, silicon nitrides, silicon dioxide, certain metals such as tungsten, nickel, molybdenum, aluminum, etc., graphene, diamond, etc., metal oxides including but not limited to aluminum oxide, hafnium oxide, zirconium oxide, etc. It should be understood that the type of films listed herein are merely exemplary and should not be construed as limiting. The CVD tool 10 can be used to deposit just about any type of thin film, not just those listed herein. The substrate 18 may be a semiconductor wafer, a flat panel display, a photovoltaic device, or any other work piece.

The type of material or film deposited on the substrate 18 is dependent on the chemistries that is/are introduced into the processing chamber 12. In non-exclusive embodiments, first and second gas(es) and/or vapors are alternatively introduced into the processing chamber 12 via the showerhead 14. For instance, first gas(es) and/or vapor(s) containing the material to be deposited is introduced into the chamber 12. Once the first gas(es) and/or vapor(s) is/are dispersed within the chamber 12, then the second reactant gas(es) and/or vapor(s) is/are introduced into the chamber 12. Alternatively, the first and second gas(es) and/or vapor(s) may be simultaneously dispersed within the chamber 12.

Regardless of the timing of the delivery, exemplary chemistries may include, but are not limited to, silane (SiH₄) or trichlorosilane SiHCl₃) for the deposit of polysilicon, silane and oxygen (O₂), dichlorosilane (SiH₂Cl₂), nitrous oxide (N₂O) and/or tetraethylorthossilicate (TEOS) for the deposit of silicon dioxide, tungsten precursors, such as tungsten hexaflouride (WF₆) for the deposit of tungsten, molybdenum precursors, such as molybdenum trioxide (MoO₃) or ammonium heptamolybdate (AHM) for the deposit of molybdenum, Bis(tertiary-butylamino)silane (BTBAS), which is a precursor for silicon nitride and silicon oxide, etc. The reactant chemistry typically includes ammonia, water, alcohol, or a combination of water and alcohol, etc. It should be noted the above-listed chemistries are merely exemplary and in no way should be construed as limiting. Again, depending on the type of film to be deposited, the first and second gas(es) and/or vapors used within the processing chamber 12 may widely vary and are far too numerous to practically list herein.

The process and reactant chemistries introduced to the showerhead 14 are typically in gas and/or liquid form. The process and reactant chemistries are then typically heated within the showerhead 14. As a result, the process and reactant chemistries are preferably in gas state form at the faceplate 36. However, in some circumstances, some portion of the process and reactant chemistries may either condense or not entirely convert into the gas state at the faceplate 36. Regardless, the general objective of the showerhead 14 is to achieve a thorough mixing of the process and reactant chemistries, at desired concentration levels or ranges, in the area of the processing chamber 12 above the substrate 18.

During processing of the substrate 18, the first and second gas(es) and/or vapor(s) are introduced and dispersed into the processing chamber by the showerhead 14 via one or more plenums (not illustrated). An RF potential, generated by the RF generator 20, is then applied to an electrode (not illustrated) on the showerhead 14. (Note, an RF potential may also possibly be applied to the substrate holder 16 as well). The RF potential results in the generation of a plasma 22 in the processing chamber 12. Within the plasma 22, energized electrons ionize or dissociate (i.e., “crack”) from the gas(es) and/or vapors in the processing chamber 12, creating chemically reactive radicals. As these radicals react, they deposit and form a thin film onto the substrate 18.

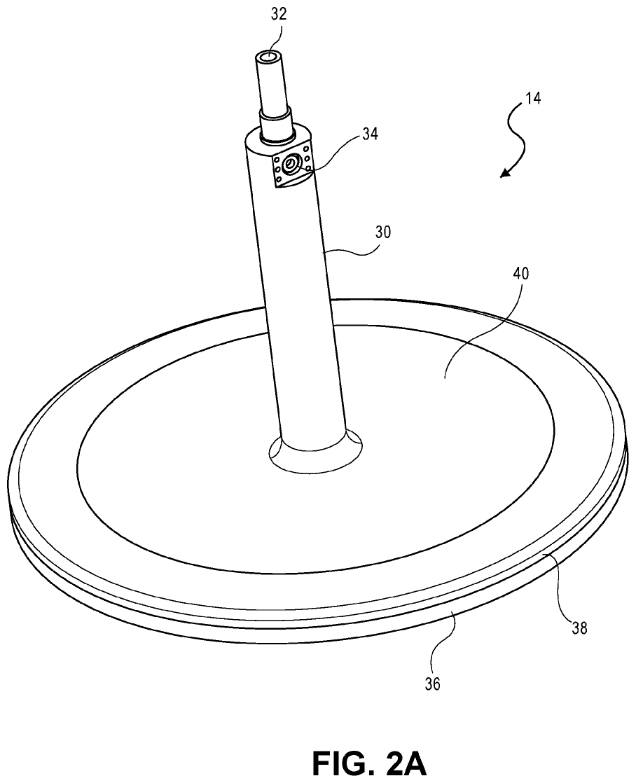

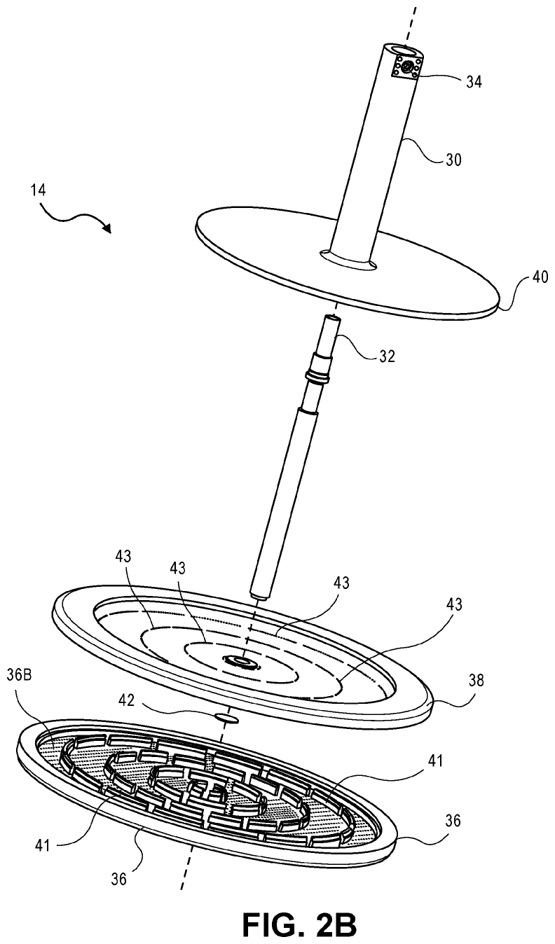

Referring to FIGS. 2A-2B, perspective and exploded views of the showerhead 14 are illustrated. The showerhead 14 includes, a stem 30 for housing a first plenum 32 and a second plenum (not visible), an inlet 34 fluidly connected to the second plenum, a faceplate 36 having a backside 36B (not visible in FIG. 2A), an intermediate plate 38 and a back plate 40. As visible in FIG. 2B, the backside 36B of the faceplate 36 further includes “ribs” or protrusions 41 that are arranged in concentric circles and that extend in the direction toward the intermediate plate 38. A diffuser 42 is provided between the faceplate 36 and the intermediate plate 38. The intermediate plate 38 includes a set of holes or slots 43, which in the particular embodiment shown, are arranged in a pattern of concentric circles that are aligned with the protrusions 41. It is noted that the stem 30 and the back plate 40 can be fabricated as a unitary piece or can be separately fabricated and then mechanically joined to form a unitary piece using any number of joining techniques, such as welding, brazing, etc.

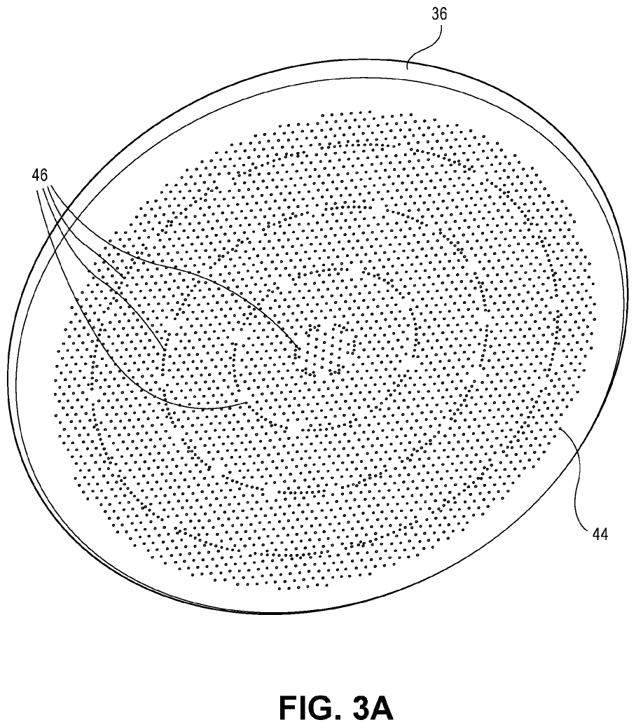

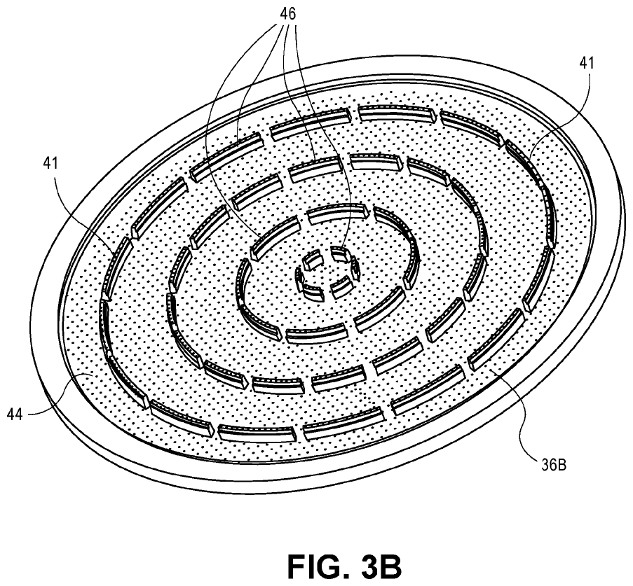

Referring to FIGS. 3A-3B, perspective views of the faceplate 36 and backside 36B are illustrated.

As best illustrated in FIG. 3A, the faceplate 36 includes first set of holes 44 and a second set of holes 46. In the embodiment shown, the first set of holes 44 are evenly spaced across the surface of the faceplate 36, while the second set of holes 46 are arranged in concentric circles that are aligned with the protrusions 41 and the set of holes or slots 43 provided through the intermediate plate 38.

As visible in FIG. 3B, the first set of holes 44 extend through the thickness of the faceplate 36 to the backside 36B. The second set of holes 46 extend from the faceplate 36 and through the protrusions 41. With this arrangement, as described in more detail below, separate gas(es) and/or vapors can be provided into the processing chamber 12 via (a) the first set of holes 44 and (b) the second set of holes 46 respectively.

It should be understood that the holes 44, 46, as illustrated, are merely exemplary and should not be construed as limiting. In alternative embodiments, the first set of holes 44 and the second set of holes 46 may be arranged in any pattern, hole quantity, pitch, diameter, etc., that is suitable for distributing and mixing, at desired concentration levels, the first and second gas(es) and/or vapors within the processing chamber 12. With this objective in mind, the holes 44, 46 may be arranged in even or uneven patterns, in concentric or non-concentric patterns, in various spiral patterns, or multiple varying distance radial patterns. To the extent a concentric pattern is used, the concentric pattern can be squares, rectangles, ovals, polygons or just about any other shape or pattern.

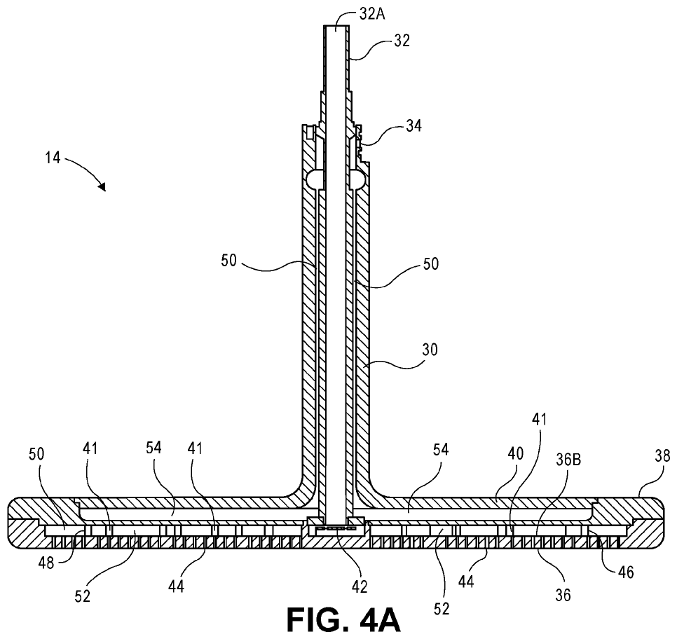

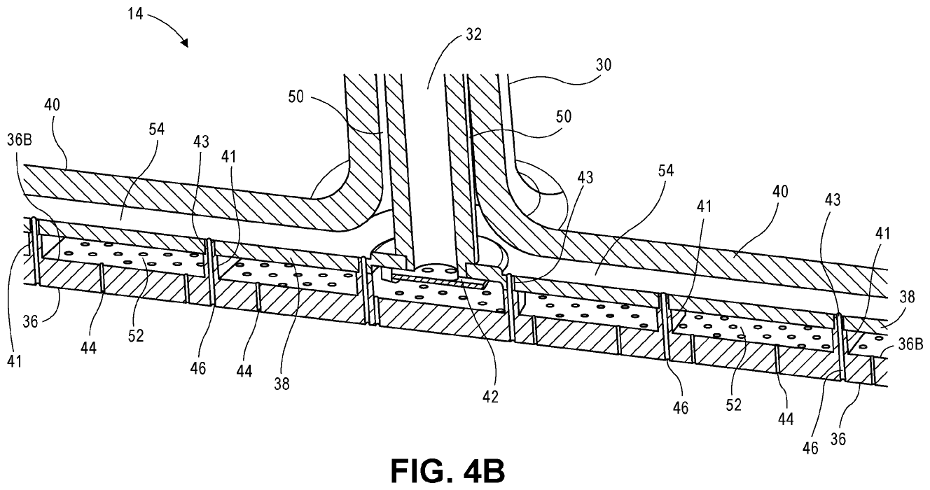

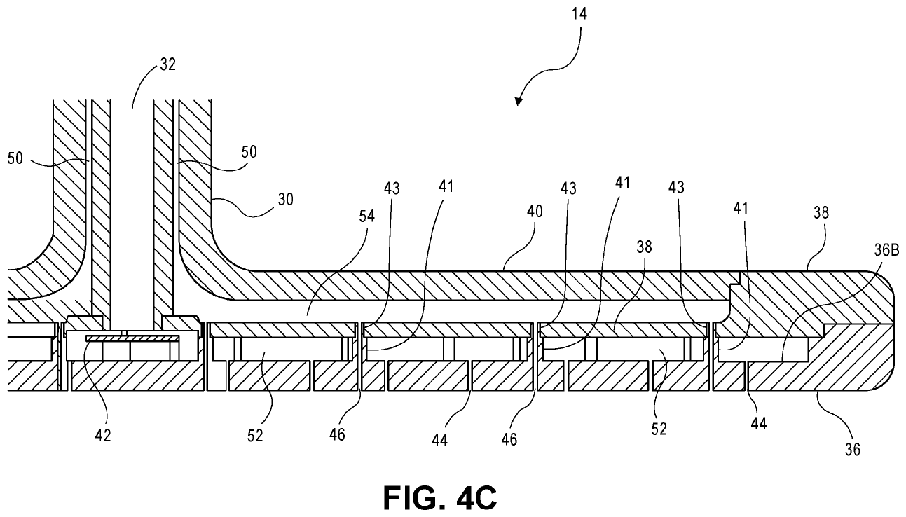

Referring to FIGS. 4A-4C, various cross section views of the assembled showerhead 14 are illustrated. As evident in these figures, the showerhead 14 includes the stem 30, the faceplate 36 including the back surface 36B, the intermediate plate 38 and the back plate 40.

The stem 30 is cylindrical in shape. The first plenum 32 extends longitudinally through the cylinder define by the stem 30. The second plenum 50, which was not visible in the previous figures, is defined within the outer and inner walls of the cylindrical stem 30.

The showerhead 14 includes two chambers 52 and 54:

(1) The first chamber 52 is defined by the space between the intermediate plate 38 and the backside 36B of the faceplate 36. An inlet 32A is provided at an end of the first plenum that is distal to the faceplate 36. The first chamber 52 is in fluid communication with, and is supplied by, the first plenum 32. With this arrangement, the first chamber 52 is provided immediately behind the backside 36B of the faceplate 36.

It should be understood that the term “immediate” as used herein means there is no chamber for distributing gas(es) and/or vapor(s) into the processing chamber 12 provided between the first chamber 52 and the backside 36B. The term immediate, however, is intended to be broadly construed to mean that other mechanical features or elements may possibly be provided between the chamber 52 and the backside 36B.

(2) The second chamber 54 is defined by the space between the intermediate plate 38 and the back plate 40. The inlet 34 is fluidly connected to the second plenum 50. The second chamber 54 is in fluid communication with, and is supplied by, the second plenum 50.

The protrusions 41 extend from the backside 36B, through the first chamber 52, into contact with the intermediate plate 38. Since the holes 46, which extend upward through the protrusions 41, are aligned with the holes or slots 43 formed in the intermediate plate 38, the second chamber 54 is in fluid communication with the processing chamber 12 via the holes 46.

The first gas and/or liquid chemistry is supplied to the showerhead 14 via the inlet 32A of the first plenum 32. Within the showerhead, the gas and/or liquid is heated, becoming either entirely a gas or a gas and/or vapor. As the first gas and/or vapor flows down the plenum 32 toward the faceplate 36, it is diffused by the diffuser 42 and enters the first chamber 52. Within the first chamber 52, the first gas and/or vapor flows in directions (a) perpendicular to the axis (e.g., the Z axis) defined by the plenum 32, (b) laterally relative to the faceplate 36 and (c) into the process chamber 12 through the first set of holes 44, which are also axial to the first plenum 32.

The second plenum 50 is arranged to receive a second gas and/or liquid via the inlet 34. Within the showerhead, the gas and/or liquid is heated, becoming either entirely a gas or a gas and/or vapor. As the second gas and/or vapor flows down the plenum 50 toward the faceplate 36, it enters the second chamber 54. Within the second chamber 54, the second gas and/or vapor flows in directions (a) perpendicular to the axis (e.g., the Z axis) defined by the plenum 50, (b) laterally relative to the faceplate 36 of the showerhead 14 and (c) through the aligned holes or slots 43 and the holes 46 and into the process chamber 12. The holes or slots 43 and the holes 46 are also both axial to the plenum 50.

With the above-described arrangement, the first and second gas(es) and/or vapor(s) are kept separate inside the showerhead 14. Once they exit the faceplate 36, the first and second gas(es) and/or vapor(s) are then free to mix within the processing chamber 12.

With the embodiments as described above, the first and second gas(es) and/or vapors are enabled to laterally flow relative to the backside 36A of the faceplate 36 within the first and second chambers 52, 54 without having to flow through a network of drilled cross-holes. As result, a number of benefits are realized, including (1) less complexity and cost in machining the showerhead, (2) a reduction or elimination of metal shavings, particles and residual oil that otherwise results from drilling, (3) a more even distribution of gas(es) and/or vapors exiting the showerhead, (4) a reduction or elimination of condensation of the gas(es) and/or vapors and (5) elimination of particles and defects on substrates.

It should be understood that while the embodiments described herein were largely related to deposition and etching tools, this should be by no means construed as limiting. On the contrary, the subject matter as described herein may be used with any type of work piece processing tool, regardless of the type of work piece or how the work piece is processed.

It should be understood that the embodiments provided herein are merely exemplary and should not be construed as limiting in any regard. Although only a few embodiments have been described in detail, it should be appreciated that the present application may be implemented in many other forms without departing from the spirit or scope of the disclosure provided herein. Therefore, the present embodiments should be considered illustrative and not restrictive and is not to be limited to the details given herein, but may be modified within the scope and equivalents of the appended claims.

1. A deposition tool, comprising:
a processing chamber;
a substrate holder configured to hold a substrate within the processing chamber; and
a showerhead having a faceplate configured to distribute a first gas and/or vapor into the processing chamber, the showerhead comprising:
a first plenum;
a first chamber provided immediately behind a backside of the faceplate; and
a first set of holes formed through the faceplate and in fluid communication with the first chamber.

2. The deposition tool of claim 1, further comprising:
a second plenum,
a second chamber arranged such that the first chamber is provided between the second chamber and the backside of the faceplate;
a second set of holes formed in the faceplate and which are in fluid communication with the processing chamber via protrusions that extend through the first chamber, the second set of holes configured to distribute a second gas and/or vapor into the processing chamber.

3. The deposition tool of claim 1, wherein the first gas and/or vapor is enabled to laterally flow relative to the backside of the faceplate within the first chamber without having to flow through cross-holes drilled through the showerhead.

4. The deposition tool of claim 2, wherein the second gas and/or vapor is enabled to laterally flow relative to the backside of the faceplate within the second chamber without having to flow through cross-holes drilled through the showerhead.

5. The deposition tool of claim 1, wherein:
the first set of holes formed through the faceplate and the first plenum extend in a first axial direction; and
the first gas and/or vapor is enabled to laterally flow within the first chamber, relative to the backside of the faceplate, in second axial directions that are perpendicular to the first axial direction.

6. The deposition tool of claim 2, wherein:
the second set of holes formed through the faceplate and the second plenum extend in a first axial direction; and
the second gas and/or vapor is enabled to laterally flow within the second chamber, relative to the backside of the faceplate, in second axial directions that are perpendicular to the first axial direction.

7. The deposition tool of claim 1, wherein the first plenum, first chamber and first set of holes are arranged to:
(a) supply a first gas and/or vapor to the first chamber via the first plenum;
(b) enable the first gas and/or vapor to flow within the first chamber laterally relative to the faceplate; and
(c) distribute the first gas and/or vapor from the first chamber into the processing chamber via the first set of holes formed through the faceplate.

8. The deposition tool of claim 2, wherein the second plenum, second chamber, and the second set of holes arranged to:
(d) supply a second gas and/or vapor to the second chamber via the second plenum;
(e) enable the second gas and/or vapor to flow within the second chamber laterally relative to the faceplate; and
(f) distribute the second gas and/or vapor from the second chamber into the processing chamber via the second set of holes formed through the faceplate.

9. The deposition tool of claim 2, wherein the showerhead further comprises a stem, the stem including the first plenum and the second plenum.

10. The deposition tool of claim 1, wherein the showerhead further comprises an intermediate plate that is positioned adjacent to the backside of the faceplate, the intermediate plate and the backside of the faceplate at least partially defining the first chamber.

11. The deposition tool of claim 2, wherein the showerhead further comprises:
an intermediate plate that is positioned adjacent to the backside of the faceplate, the intermediate plate and the backside of the faceplate at least partially defining the first chamber; and
a back plate positioned next to the intermediate plate, the back plate and the intermediate plate at least partially defining the second chamber.

12. The deposition tool of claim 1, wherein the first set of holes are evenly arranged on the faceplate of the showerhead.

13. The deposition tool of claim 2, wherein the second set of holes are arranged in a concentric pattern on the faceplate of the showerhead.

14. The deposition tool of claim 13, wherein the concentric pattern is one of the following:
(a) concentric circles:
(b) concentric squares:
(c) concentric rectangles;
(d) concentric ovals; or
(e) concentric polygons.

15. The deposition tool of claim 2, wherein the first set of holes is larger in number than the second set of holes and the second gas and/or vapor is easier to disperse within the processing chamber relative to the first gas and/or vapor.

16. The deposition tool of claim 1, wherein the first gas and/or vapor is a process chemistry that contains a material to be deposited on the substrate when processed in the processing chamber.

17. The deposition tool of claim 2, wherein the first gas and/or vapor and the second gas and/or vapor are isolated and separated from one another inside the showerhead, but are free to mix outside the showerhead inside the processing chamber.

18. The deposition tool of claim 2, wherein the first gas and/or vapor is a process chemistry that contains a material to be deposited on the substrate when processed in the processing chamber and the second gas and/or vapor is a reactant gas and/or vapor.

19. The deposition tool of claim 2, wherein the first gas and/or vapor is a reactant gas and/or vapor and the second gas and/or vapor is a process chemistry that contains a material to be deposited on the substrate when processed in the processing chamber.

20. A showerhead, comprising:
a faceplate configured to distribute one or more of a first gas and/or vapor into a processing chamber;
a first plenum;
a first chamber provided immediately behind a backside of the faceplate in fluid communication with the first plenum; and
a first set of holes formed through the faceplate and in fluid communication with the first chamber.

21. The showerhead of claim 20, further comprising:
a second plenum,
a second chamber in fluid communication with the second plenum and arranged such that the first chamber is provided between the second chamber and the backside of the faceplate;
a second set of holes formed in the faceplate, which are in fluid communication with the processing chamber via protrusions that extend through the first chamber, the second set of holes configured to distribute one or more of a second gas and/or vapor into the processing chamber.

22. The showerhead of claim 21, wherein the one or more of the first gas and/or vapor is enabled to laterally flow relative to the backside of the faceplate within the first chamber without having to flow through cross-holes drilled through the showerhead.

23. The showerhead of claim 21, wherein the at least one second gas and/or vapor is enabled to laterally flow relative to the backside of the faceplate within the second chamber without having to flow through cross-holes drilled through the showerhead.

24. The showerhead of claim 21, wherein:
the first set of holes formed through the faceplate and the first plenum extend in a first axial direction; and
the one or more of the first gas and/or vapor is enabled to laterally flow within the first chamber, relative to the backside of the faceplate, in second axial directions that are perpendicular to the first axial direction.

25. The showerhead of claim 21, wherein:
the second set of holes formed through the faceplate and the second plenum extend in a first axial direction; and
the one or more of the second gas and/or vapor is enabled to laterally flow within the second chamber, relative to the backside of the faceplate, in second axial directions that are perpendicular to the first axial direction.

26. The showerhead of claim 21, wherein the first plenum, first chamber and first set of holes are arranged to:
(a) supply the one or more of the first gas and/or vapor to the first chamber via the first plenum;
(b) enable the one or more of the first gas and/or vapor to flow within the first chamber laterally relative to the faceplate; and
(c) distribute the one or more of the first gas and/or vapor from the first chamber into the processing chamber via the first set of holes formed through the faceplate.

27. The showerhead of claim 21, wherein the second plenum, second chamber, and the second set of holes arranged to:
(d) supply the one or more of the second gas and/or vapor to the second chamber via the second plenum;
(e) enable the one or more of the second gas and/or vapor to flow within the second chamber laterally relative to the faceplate; and
(f) distribute the one or more of the second gas and/or vapor from the second chamber into the processing chamber via the second set of holes formed through the faceplate.

28. The showerhead of claim 21, further comprising a stem, the stem including the first plenum and the second plenum.

29. The showerhead of claim 21, further comprising:
an intermediate plate that is positioned adjacent to the backside of the faceplate, the intermediate plate and the backside of the faceplate at least partially defining the first chamber; and
a back plate positioned next to the intermediate plate, the back plate and the intermediate plate at least partially defining the second chamber.

30. The showerhead of claim 21, wherein the first set of holes are evenly arranged on the faceplate of the showerhead.

31. The showerhead of claim 21, wherein the second set of holes are arranged in a concentric pattern on the faceplate of the showerhead.

32. The showerhead of claim 31, wherein the concentric pattern is one of the following:
(a) concentric circles:
(b) concentric squares:
(c) concentric rectangles;
(d) concentric ovals; or
(e) concentric polygons.

33. The showerhead of claim 21, wherein the first set of holes is larger in number than the second set of holes and the one or more of the second gas and/or vapor is easier to disperse within the processing chamber relative to the one or more of the first gas and/or vapor.

34. The showerhead of claim 21, wherein the one or more of the first gas and/or vapor and the one or more of the second gas and/or vapor are isolated and separated from one another inside the showerhead, but are free to mix outside the showerhead inside the processing chamber.
